(19) United States
(12) Patent Application Publication
(10) Pub. No.: US 2008/0035991 A1
(43) Pub. Date: Feb. 14, 2008

(54) Transistor Having Recess Channel Structure and Fin Structure, Semiconductor Device Employing the Transistor, and Method of Fabricating the Semiconductor Device

(76) Inventors: Sang-Hyeon Lee, Suwon-si (KR); Kyoung-Ho Kim, Seoul (KR)

Correspondence Address: F. CHAU & ASSOCIATES, LLC, 130 WOODBURY ROAD, WOODBURY, NY, 11797, US

(21) Appl. No.: 11/696,541

(22) Filed: Apr. 4, 2007

(30) Foreign Application Priority Data
Aug. 11, 2006 (KR) 10-2006-0076303

(51) Int. Cl. H01L 31/00

(52) U.S. Cl. 257/331

(57) ABSTRACT

A semiconductor device includes an upper gate trench crossing an active region of a semiconductor substrate, a lower gate trench overlapping the upper gate trench at both ends, disposed at a lower level than the upper gate trench, and having a smaller width than the upper gate trench and wherein the lower gate trench is spaced apart from sidewalls of the upper gate trench. The semiconductor device further includes a gate pattern partially covering the bottom of the upper gate trench between the sidewall of the upper gate trench and the lower gate trench, filling the lower gate trench, and covering sidewalls of the active region adjacent to the bottom and sidewalls of the lower gate trench.

### CROSS-REFERENCE TO RELATED APPLICATION

This application claims the benefit of Korean Patent Application No, 10-2006-0076303, filed Aug. 11, 2006, the disclosure of which is hereby incorporated by reference herein in its entirety.

### BACKGROUND OF THE INVENTION

1. Technical Field

The present disclosure relates to a semiconductor device and a method of fabricating the same, and more particularly, to a transistor having a recess channel structure and a fin structure, a semiconductor device employing the transistor, and a method of fabricating the semiconductor device,

2. Description of the Related Art

Discrete devices such as, for example, a field effect transistor have been widely adopted as a switching device in semiconductor devices. With the transistor, the operating speed of the device is determined by on-current flowing in a channel between a source region and a drain region. Generally, a gate electrode and source and drain regions are formed in a device-forming region of a substrate, e.g., an active region, and thus a planar transistor may be fabricated. A common planar transistor has a planar channel between source and drain regions. The on-current of the planar transistor is directly proportional to the width of the active region and inversely proportional to the distance between the source and drain regions, e.g., gate length. Accordingly, to increase the operating speed of the device by increasing the on-current, the gate length should be reduced, and the width of the active region should be increased. However in the planar transistor, increasing the width of the active region goes against the recent trend toward high-integration. Also, as the distance between the source and drain regions becomes shorter, a short channel effect may occur in the planar transistor. Thus, to make a transistor having a short channel suitable for in use in next generation devices, the short channel effect should be prevented, However, the conventional planar transistor having a channel parallel to the semiconductor surface is a planar channel device, which is typically not appropriate for reducing the size of the device or preventing the short channel effect.

Therefore, a transistor having a recess channel has been proposed in an attempt to overcome the above-mentioned short channel effect and also to reduce the size of the transistor. The recess channel transistor includes a recess channel region and an insulated gate electrode. The insulated gate electrode is disposed on the recess channel region. Accordingly, the recess channel transistor has an effective channel length which is relatively longer than that of the planar transistor. As a result, the recess channel transistor provides a structure that can solve the difficulties caused by the short channel effect. However, the recess channel transistor has a relatively unfavorable structure compared to the planar transistor in terms of on-current characteristics and a body effect. Therefore, there may be limitations with regard to employing the recess channel transistor in low-power consumption and high-performance semiconductor products.

As a substitute device structure for the conventional planar transistor, a double gate field effect transistor has been proposed. The double gate field effect transistor has gates on both sides of a channel, thereby effectively controlling the electric potential of the channel. In addition, in an effort to fabricate a double gate field effect transistor having top and bottom gates using in conventional semiconductor fabrication technology, a fin field effect transistor (Fin-FET) has been proposed. For example, Chenming Hu et al. describes a double gate on a fin channel which can inhibit the short channel effect and increase driving current in U.S, Pat. No. 6,413,802 B1, entitled “Fin-FET Transistor Structure Having a Double Gate Channel Extending Vertically From a Substrate and Methods of Manufacture.” Unlike the planar transistor, the Fin-FET double gate device includes a vertical channel and thus is well suited for reducing the size of devices. The above-mentioned Fin-FET double gate device is also highly compatible with conventional technology for manufacturing the planar transistor. Also, a method of fabricating a Fin-FET used as a cell transistor of a memory cell array is described in U.S. Patent Publication No. 200510153490 A1, entitled “Method of Forming Fin Field Effect Transistor” by Yoon et al. While such a Fin-FET may have enhanced on-current characteristic. body effect, and sub-threshold swing characteristic, gate induced drain leakage (GIDL) caused by an increase in overlap area between source and drain regions and a gate electrode, a field concentration effect, and so on may be increased to thereby degrade performance of a transistor Thus, when a Fin-FET is adopted as a cell transistor of a DRAM, it may be difficult to ensure the data retention characteristics of the DRAM.

Accordingly, there is a need for a transistor for a semiconductor device wherein the short channel effect can be inhibited and the on-current characteristics of the transistor are improved as well.

### SUMMARY OF THE INVENTION

Exemplary embodiments of the present invention provide a semiconductor device employing a transistor having a fin structure and a recess channel structure.

Another exemplary embodiment of the present invention provides a method of fabricating a semiconductor device employing a transistor having a fin structure and a recess channel structure.

Still another exemplary embodiment of the present invention provides a method of fabricating a semiconductor device employing a transistor having a fin structure and a recess channel structure as a memory cell transistor.

In an exemplary embodiment of the present invention, a semiconductor device is provided. The device includes an upper gate trench crossing an active region of a semiconductor substrate, and a lower gate trench.

The lower gate trench overlapping the upper gate trench at both ends, disposed at a lower level than the upper gate trench, and having a smaller width than the upper gate trench and wherein the lower gate trench is spaced apart from sidewalls of the upper gate trench. The device further includes a gate pattern partially covering the bottom of the upper gate trench between the sidewall of the upper gate trench and the lower gate trench, filling the lower gate trench, and covering sidewalls of the active region adjacent to the bottom and sidewalls of the lower gate trench.

In some exemplary embodiments of the present invention, the gate in pattern may be spaced apart from the sidewalls of the upper gate trench.

In other exemplary embodiments, the device may further include an insulating spacer interposed between the sidewall of the upper gate trench and the gate pattern. Furthermore, the device may further comprise source and drain regions disposed in the active region adjacent to sidewalls and the bottom of the insulating spacer.

In still other exemplary embodiments, the device may further include a data storage element electrically connected to one of the source and drain regions.

In yet other exemplary embodiments, the gate pattern may include a gate dielectric layer and a gate electrode which are sequentially stacked.

In yet other exemplary embodiments, the longitudinal width of the active region adjacent to the bottom of the lower gate trench covered by the gate pattern may be equal to or greater than the lateral width of the active region adjacent to the sidewall of the lower gate trench covered by the gate pattern.

In another exemplary embodiment of the present invention a method of fabricating a semiconductor device is provided. The method includes forming an isolation layer defining an active region in a semiconductor substrate. An upper gate trench crossing the active region of the semiconductor substrate is formed. A lower gate trench having a smaller width than the upper gate trench is formed to overlap the upper gate trench at both ends and wherein the lower gate trench is spaced apart from sidewalls of the upper gate trench by partially in etching the bottom of the upper gate trench. The isolation layer adjacent to the lower gate trench is partially etched to expose sidewalls of the active region adjacent to the bottom and sidewalls of the lower gate trench. A gate pattern Is formed which fills the lower gate trench, covers the sidewall of the active region adjacent to the bottom and sidewall of the exposed lower gate trench, and partially covers the bottom of the upper gate trench and wherein the gate pattern is spaced apart from the sidewall of the upper gate trench.

In some exemplary embodiments of the present invention, the forming of the upper gate trench may include forming a mask partially exposing the active region and the isolation layer on the substrate having the isolation layer, and etching the active region using the mask as an etch mask.

In other exemplary embodiments, the forming of the lower gate trench may include partially etching the isolation layer using the mask as an etch mask, forming a sacrificial spacer on the sidewalls of the upper gate trench and the mask and etching the bottom of the upper gate trench using the mask and the sacrificial spacer as etch masks.

In still other exemplary embodiments, partially etching the isolation layer adjacent to the lower gate trench may include etching the isolation layer adjacent to the lower gate trench using an isotropic etching process having a high etch rate with respect to the isolation layer, and removing the sacrificial spacer and the mask.

In yet other exemplary embodiments, forming the gate pattern may include forming a gate layer on the substrate exposing sidewalls of the active in region adjacent to the sidewalls and bottom of the lower gate trench, and patterning the gate layer.

In yet other exemplary embodiments, the method may further include forming an insulating spacer filling a space between the sidewall of the upper gate trench and the gate pattern. Furthermore, the method may also comprise forming source and drain regions in the active region adjacent to the sidewalls and bottom of the insulating spacer. Here, the forming of the source and drain regions may include injecting impurity ions into the active region adjacent to the sidewalls of the upper gate trench and diffusing the impurity ions into the active region adjacent to the bottom of the insulating spacer.

In yet other exemplary embodiments, the method may further comprise forming a data storage element electrically connected to one of the source and drain regions.

In still another exemplary embodiment of, the present invention a method of fabricating a semiconductor device is provided. The method includes forming an isolation layer defining a plurality of active regions each having major and minor axes and the plurality of active regions are two-dimensionally arranged along the major and minor axes in a semiconductor substrate. An upper trench crossing the active regions of the semiconductor substrate and extending to the isolation layer is formed. A lower gate trench having a smaller width than the upper trench is formed to overlap the upper trench at both ends and wherein the lower gate trench is spaced apart from sidewalls of the upper trench in the active in region by partially etching the bottom of the upper trench disposed in the active regions. A lower field trench having a greater width and a lower bottom than the lower gate trench is formed by partially etching the isolation layer adjacent to the lower gate trench to expose sidewalls of the active regions adjacent to the bottom and sidewall of the lower gate trench. A gate pattern is formed which fills the lower gate trench and the lower field trench, and partially covers the bottom of the upper trench to be spaced apart from sidewalls of the upper trench disposed in the active regions.

In some exemplary embodiments of the present invention, forming the upper trench may include forming a mask having an opening partially exposing the active regions and the isolation layer. The mask may include a lower hard mask, an upper hard mask and a sacrificial mask which are sequentially stacked, and the upper hard mask may be formed of a material having an etch selectivity with respect to the lower hard mask and the isolation layer. Then the active regions and the isolation layer exposed by the opening may be etched using the mask as an etch mask, and the sacrificial mask may be removed. Here, the opening may have a pocket structure and thus the isolation layer between the active regions arranged along the major axis may be covered by the mask.

In other exemplary embodiments, the forming of the lower gate trench may include forming a sacrificial spacer covering the lower hard masks the upper hard mask and the sidewall of the upper trench, anisotropically etching the bottom of the upper trench disposed in the active regions using the sacrificial spacer and the upper hard mask as etch masks and removing the upper hard in mask. Here, when the upper hard mask is formed of the same material as the active regions, the upper hard mask may be etched and removed while etching the bottom of the upper trench disposed in the active regions.

In still other exemplary embodiments, the forming of the lower field trench may include anisotropically etching the isolation layer using the sacrificial spacer and the lower hard mask as etch masks and forming a preliminary lower field trench, etching the preliminary lower field trench by an isotropic etching process having a high etch rate with respect to the isolation layer using the sacrificial mask and the lower hard mask as etch masks, and removing the sacrificial spacer and the lower hard mask. Here, the preliminary lower field trench may be formed to have a bottom disposed at a lower level than the lower gate trench.

In yet other exemplary embodiments, the method may further include forming an insulating spacer filling a space between the sidewall of the upper trench and the gate pattern.

In yet other exemplary embodiments, the method may further include forming source and drain regions adjacent to sidewalls and the bottom of the insulating spacer.

In yet other exemplary embodiments, the method may further include forming a data storage element electrically connected to one of the source and drain regions.

### BRIEF DESCRIPTION OF THE DRAWINGS

Exemplary embodiments of the present invention can be understood in more detail from the following detailed description taken in conjunction with, the accompanying drawings in which:

FIG. 1 is a plan view of a semiconductor device according to an exemplary embodiment of the present invention,

FIGS. 2 to 8 are cross sectional views of a semiconductor device according to exemplary embodiments of the present invention.

### DETAILED DESCRIPTION OF THE EXEMPLARY EMBODIMENTS OF THE INVENTION

The present invention will now be described more fully with reference to the accompanying drawings, in which exemplary embodiments of the invention are shown. This invention may, however, be embodied in different forms and should not be construed as limited to the exemplary embodiments set forth herein. In the drawings, the thickness of layers and regions may be exaggerated for clarity, and like reference numerals denote like elements

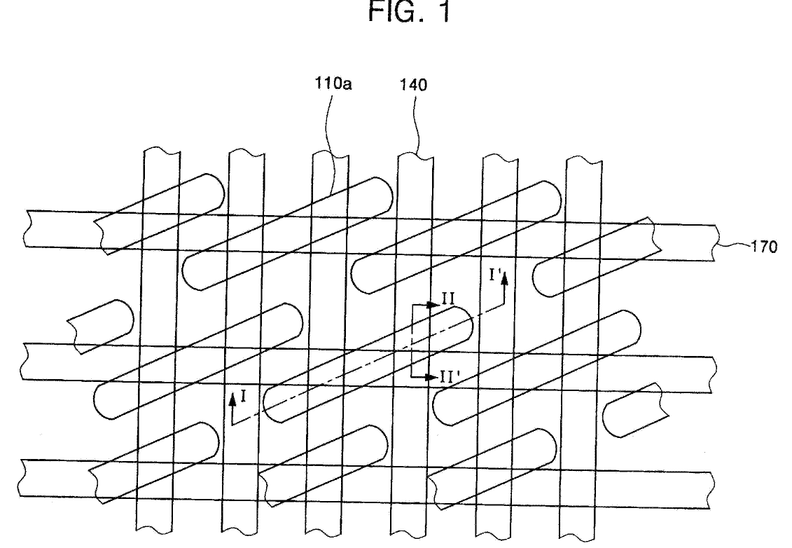

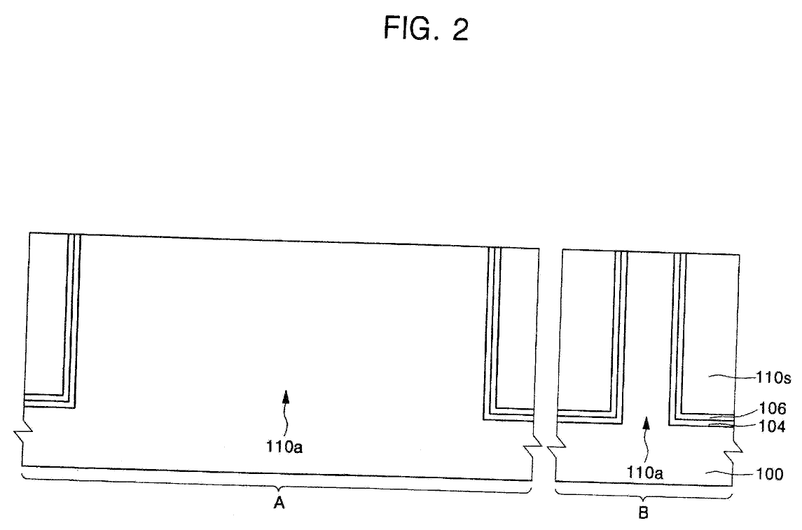

FIG. 1 is a plan view of a semiconductor device according to an exemplary embodiment of the present invention, and FIGS. 2 to 8 are cross-sectional views of a semiconductor device according to exemplary embodiments of the present invention. In FIGS. 2 to 8, reference mark “A” denotes a region taken along line I-I′ of FIG. 1, and reference mark “B” denotes a region taken along line II˜II′ of FIG. 1.

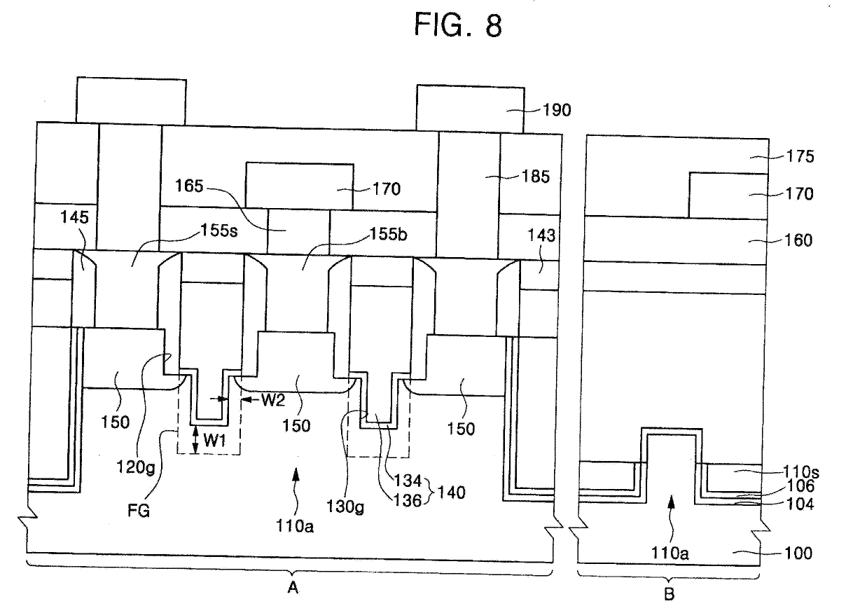

First, a semiconductor device according to exemplary embodiments of the present invention will be described with reference to FIGS. 1 and 8.

Referring to FIGS. 1 and 8, an isolation layer 110s defining an active region 110a is provided in a semiconductor substrate 100. Here, the isolation layer 110s may be a shallow trench isolation layer, The active region 110a has a major axis and a minor axis, and a plurality of active regions may be two-dimensionally arranged along the major and minor axes. An insulating liner 106 may be provided between the isolation layer 110s and the semiconductor substrate 100. The insulating liner 106 may be an insulating layer, for example, a silicon nitride layer. A buffer oxide layer 104 may be provided between the insulating liner 106 and the semiconductor substrate 100. The buffer oxide layer 104 may be an insulating layer, for example, a silicon oxide layer.

An upper gate trench 120g crossing the active region 110a may be provided. A lower gate trench 130g overlapping the upper gate trench 120g at both ends thereof and disposed at a lower level than the upper gate trench 120g may be provided. Here, the lower gate trench 130g has a smaller width than the upper gate trench 120g to be spaced apart from sidewalls of the upper gate trench 120g.

A gate pattern 140 is provided which partially covers the bottom of the upper gate trench 120g interposed between the sidewall of the upper gate trench 120g and the lower gate trench 130g so as to fill the lower gate trench 130g, and in covers sidewalls of the active region adjacent to the bottom and sidewall of the lower gate trench 130g. Here, the gate pattern 140 may be spaced apart from the sidewalls of the upper gate trench 120g. The gate pattern 140 may include a gate dielectric layer 134 and a gate electrode 136 which are sequentially stacked. The gate dielectric layer 134 may be, for example, a silicon oxide layer or a high-k dielectric layer. The gate electrode 136 may include, for example, at least one selected from a polysilicon layer, a metal layer and a silicide layer. A longitudinal width WI of the sidewall of the active region 110a, which is adjacent to the bottom of the lower gate trench 130g covered by the gate pattern 140, may be equal to or greater than a lateral width W2 of the sidewall of the active region 110a which is adjacent to the sidewall of the lower gate trench 130g covered by the gate pattern 140.

An insulating spacer 145 may be interposed between the sidewall of the upper gate trench 120g and the gate pattern 140. The insulating spacer 145 may be an insulating layer, for example, a silicon nitride layer or a silicon oxide layer.

Source and drain regions 150 may be provided in the active region 110a adjacent to the upper gate trench 120g. For example, the source and drain regions 150 are provided in the active region adjacent to the sidewalls and bottom of the insulating spacer 145. Accordingly, an overlap area between the source and drain regions 150 and the gate pattern 140 may be minimized, and thus gate induced drain leakage (GIDL) may be minimized.

The upper gate trench 130g is filled with the gate pattern 140 to form a recess channel between the source and drain regions 150. Also, the gate pattern 140 covers the sidewall of the active region 110a adjacent to the bottom and sidewall of the lower gate trench 130g, thereby forming a fin structure, Thus, a transistor having the recess channel and fin structures may be provided.

As described above, the recess channel is formed between the source and drain regions 150, thereby increasing the effective channel length of the transistor. As a result a short channel effect may be inhibited. Furthermore, a highly integrated semiconductor device may be implemented.

Also, the gate pattern 140 covers the sidewall of the active region 110a adjacent to the bottom and sidewall of the lower gate trench 130g, and partially covers the bottom of the upper gate trench 120g, thereby improving controllability for a channel of the gate electrode 140. Accordingly, even though the transistor has the recess channel, its on-current characteristic may be improved and the body effect may be inhibited, which thereby results in increased operating speed.

Furthermore, the source and drain regions 150 are provided in the active region adjacent to the upper gate trench 120g, and more specifically, in the active region adjacent to the sidewalls and bottom of the insulating spacer 145. Thus, the overlap area between the source and drain regions 150 and the gate electrode 136 may be minimized. Accordingly, an electric field between the source and drain regions 150 and the gate electrode 136 may be minimized. As a result, the GIDL of the transistor can be suppressed, and the transistor can operate at high speed with low power consumption.

A data storage element 190 electrically connected to one of the source in and drain regions 150 may be provided. The data storage element 190 may be a storage capacitor. A buried contact plug 185 may be provided between one of the source and drain regions 150 and the data storage element 190. Also, a first landing pad 155s may be provided between one of the source and drain regions 150 and the buried contact plug 185. Furthermore, a region of the source and drain regions 150, which is not electrically connected to the data storage element 190, may be electrically connected to a conductive line 170. The conductive line 170 may be defined as a bit line, and the gate electrode 136 may be defined as a word line. A direct contact plug 165 may be interposed between the conductive line 170 and the selected region of the source and drain regions 150. Also, a second landing pad 155b may be interposed between the direct contact plug 165 and the selected region of the source and drain regions 150.

As described above, the exemplary embodiments of the present invention provide a memory device such as, for example, a DRAM employing a transistor having recess channel and fin structures as a cell transistor. The provided memory device may have an improved data retention characteristic, and electronic devices employing such a DRAM may exhibit low power consumption and high performance.

A method of fabricating a semiconductor device according to exemplary embodiments of the present invention will be described below with reference to FIGS. 1 to 8.

Referring to FIGS. 1 and 2, an isolation layer 110s defining an active region 110a is formed in a semiconductor substrate 100. Here, a plurality of active regions 110a may be defined by the isolation layer 110s. In this case, each of the active regions 110a has major and minor axes, and the active regions 110a may be two-dimensionally arranged along the major and minor axes.

The isolation layer 110s may be formed using, for example, a shallow trench isolation technique. For example, forming the isolation layer 110s may include etching a predetermined region of the semiconductor substrate 110 to form an isolation trench, and forming an insulating layer filling the isolation trench. After the semiconductor substrate 100 is etched to form the isolation trench, a buffer oxide layer 104 and an insulating liner 106 may be sequentially formed on inner walls of the trench. The buffer oxide layer 104 is formed to cure damage to the semiconductor substrate 100 caused by etching during formation of the isolation trench. The buffer oxide layer 104 may be formed by, for example, thermal oxidation of the substrate having the isolation trench. The insulating liner 106 may be formed of, for example, a silicon nitride layer using a chemical vapor deposition (CVD) method. The insulating liner 106 is formed to prevent the semiconductor substrate at the inner wall of the isolation trench from being oxidized in a following thermal process for forming a semiconductor device. Also, the insulating liner 106 may prevent reduction in area of the active region 110a due to oxidation in the following thermal process.

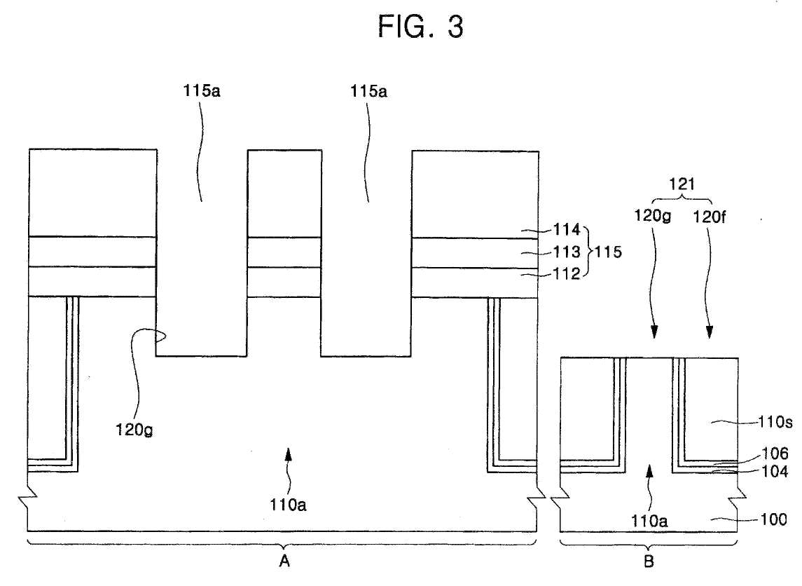

Referring to FIGS. 1 and 3, a mask 115 having an opening 115a crossing the active region 110a and extending toward the isolation layer 110s in may be formed on the substrate having the isolation layer 110s. The mask 115 may include a tower hard mask 112, an upper hard mask 113 and a sacrificial mask which are sequentially stacked, The lower hard mask 112 may be formed of a material having an etch selectivity with respect to the isolation layer 110s and the active region 110a. The upper hard mask 113 may be formed of a material having an etch selectivity with respect to the lower hard mask 112 and the isolation layer 110s. For example, when the lower hard mask 112 is a silicon nitride layer, the upper hard mask 113 may be a silicon layer or an amorphous carbon layer, The sacrificial mask may be formed of, for example, a photoresist layer.

The opening 115a of the mask 115 may be formed to have a pocket structure. For example, when there are a plurality of active regions 110a, the opening 115a may have a pocket structure extending across the active regions 110a to the isolation layer 110s, so that the isolation layer disposed between the active regions 110a arranged along the major axis of the active regions 110a may be covered by the mask 115. That is, as illustrated in FIG. 3, the isolation layer 110s disposed between the sidewalls of the active regions 110a substantially parallel to the minor axis thereof may be covered by the mask 115.

Also, prior to forming the lower hard mask 112, a pad oxide layer may be formed. When the lower hard mask 112 is formed of a silicon nitride layers the pad oxide layer may lessen stress caused by a difference in thermal expansion coefficient between the active region 110a and the lower hard mask 112.

The active region 110a exposed by the opening 115a may be etched using the mask 115 as an etch mask. Etching the active region 110a using the mask 115 as an etch mask may be performed by, for example, an anisotropic etching process. As a result, an upper gate trench 120g crossing the active region 110a may be formed.

The isolation layer 110s exposed by the opening 115a may be etched using the mask 115 as an etch mask. As a result, an uppertrench 121 including the upper gate trench 120g crossing the active region 110a and an upper field trench 120f extending from the upper gate trench 120g to the isolation layer 110s may be formed.

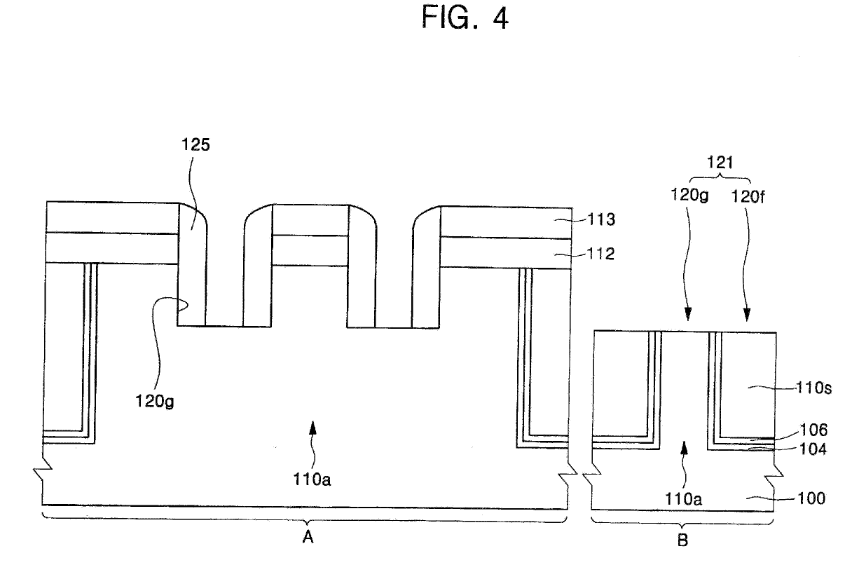

Referring to FIGS. 1 and 4, the sacrificial mask 114 may be removed. A sacrificial spacer 125 covering sidewalls of the lower hard mask 112, the upper hard mask 113 and the upper trench 121 may be formed. As a result, the bottom of the upper trench 121 may be partially exposed. That is, bottoms of the upper gate trench 120g and the upper field trench 120f may be partially exposed. The sacrificial spacer 125 may be formed of a material having the same etch rate as the lower hard mask 112. For example, when the lower hard mask 112 is formed of a silicon nitride layer, the sacrificial spacer 125 may also be formed of a silicon nitride layer.

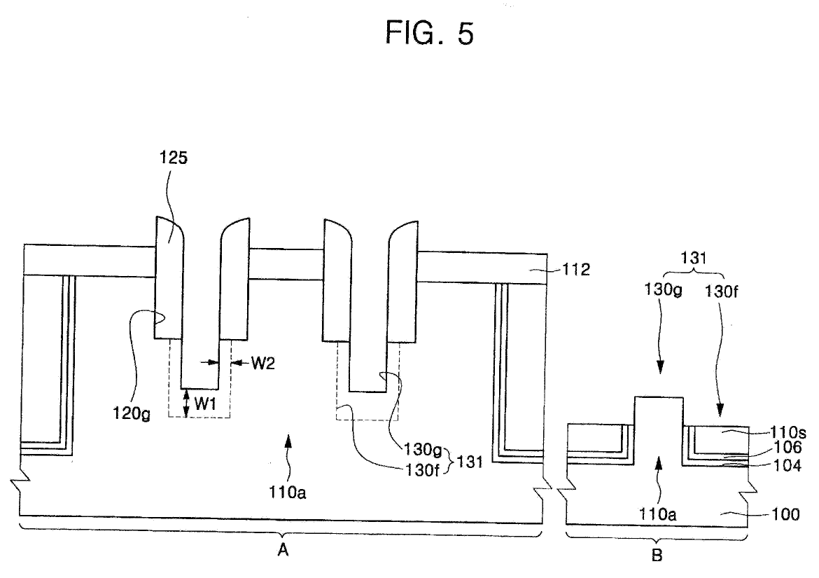

Referring to FIGS. 1 and 5, the bottom of the upper gate trench 120g is etched using the sacrificial spacer 125 and the upper hard mask 113 as etch masks so as to form a lower gate trench 130g. Here, the bottom of the upper gate trench 120g may be etched by for example, an anisotropic etch process so in that the lower gate trench 130g has a smaller width than the upper gate trench 120g. Also, both ends of the lower gate trench 130g may overlap both ends of the upper gate trench 120g, and thus a predetermined region of the isolation layer 110s may be exposed.

In other words, when the upper hard mask 113 is formed of a silicon layer and the active region 110a is formed of single crystalline silicon, the upper hard mask 113 may be etched and removed while the lower gate trench 130g is formed. Accordingly, the lower hard mask 112 and the sacrificial spacer 125 may remain, As such, when the upper hard mask 113 is formed of the same material as the active region 110a, a separate etching process for removing the upper hard mask 113 may be omitted, thus reducing the cost and time required to produce the semiconductor device. Alternatively, when the upper hard mask 113 is formed of, for example, an amorphous carbon layer, an etching process for removing the upper hard mask 113 may be performed.

The isolation layer 110s exposed by the lower gate trench 130g is partially etched using the lower hard mask 112 and the sacrificial spacer 125 as etch masks to form a lower field trench 130f exposing the sidewalls of the active region 110a adjacent to the bottom and sidewall of the lower gate trench 130g. Here, the partial etching of the isolation layer 110s exposed by the lower gate trench 130g may be performed by, for example, an isotropic etching process having a high etch rate with respect to the isolation layer 110s. Accordingly, a longitudinal width WI of the sidewall of the exposed active region 110a adjacent to the bottom of the lower gate trench 130g may be the same as a lateral width in W2 of the sidewall of the exposed active region 110a adjacent to the sidewall of the lower gate trench 130g.

Alternatively, a preliminary lower field trench may be formed by, for examples anisotropically etching the bottom of the upper field trench 120f using the lower hard mask 112 and the sacrificial spacer 125 as etch masks. Then, the isolation layer of the sidewalls and bottom of the preliminary lower field trench may be, for example, isotropically etched to form a lower field trench 130f exposing the sidewall of the active region adjacent to the bottom and sidewall of the lower gate trench 130g. As a result, a tower trench 131 including the lower gate trench 131a and the lower field trench 130f may be formed. In addition, to further improve the on-current characteristic of the completed transistor, the preliminary tower field trench may be formed to have a lower bottom than the lower gate trench 130f. Thus, the lower field trench 130f may expose the sidewall of the active region 110a adjacent to the sidewall and bottom of the tower gate trench 130g. Here, the longitudinal width W1 of the sidewall of the exposed active region 110a adjacent to the bottom of the lower gate trench 130g may be greater than the lateral width W2 of the sidewall of the exposed active region 110a adjacent to the sidewall of the tower gate trench 130g. Thus, the overlap area between the gate pattern formed by the following process and the sidewall of the active region 110a is increased, and thereby the oncurrent characteristic of the transistor may be improved. That is, the operating speed of the transistor may be improved.

Consequently, the longitudinal width W1 of the sidewall of the exposed in active region 110a adjacent to the bottom of the lower gate trench 130g may be equal to or greater than the lateral width W2 of the sidewall of the exposed active region 110a adjacent to the sidewall of the lower gate trench 130g.

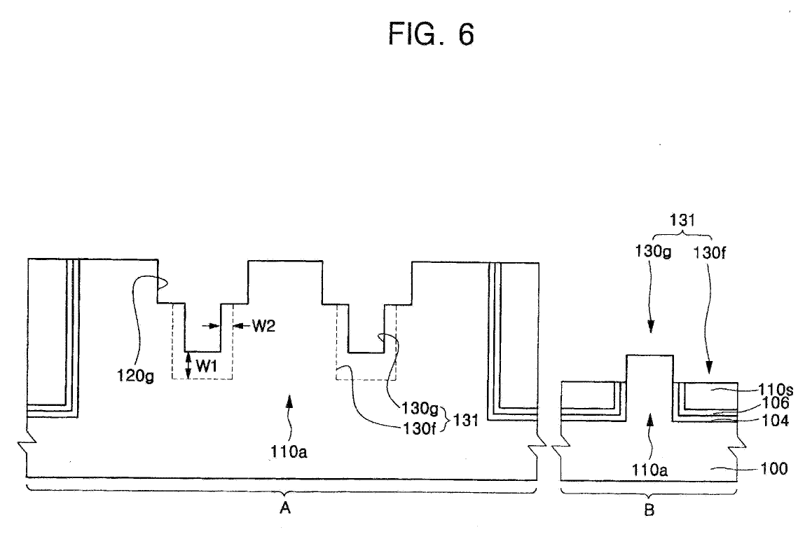

Then, the lower hard mask 112 and the sacrificial spacer 125 may be removed to expose the sidewall and bottom of the upper gate trench 120g as illustrated in FIG. 6.

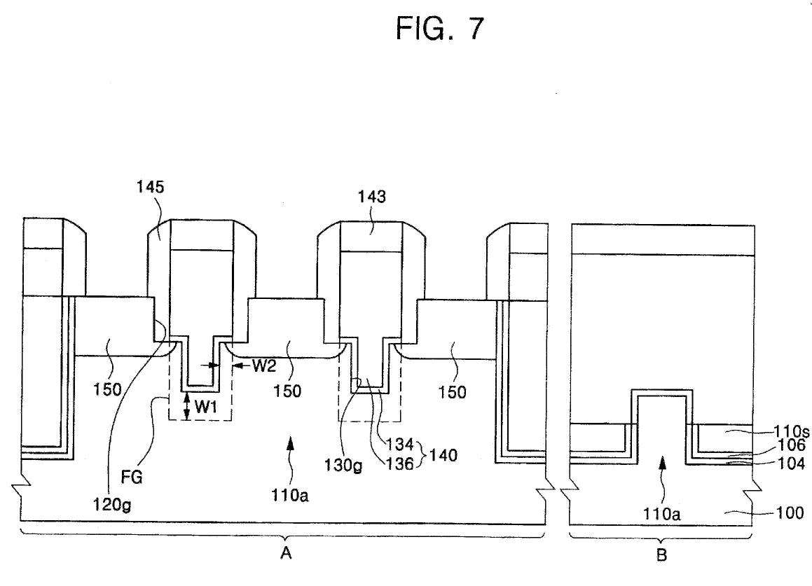

Referring to FIGS. 1 and 7, a gate pattern 140 filling the lower trench 131 and partially covering the bottom of the upper gate trench 120g to be spaced apart from the sidewall of the upper gate trench 120g is formed. The gate pattern 140 is formed to fill the lower gate trench 130g and the lower field trench 139f, and thus the sidewall of the active region 110a exposed by the lower field trench 130f may be covered. In FIG. 7, reference mark “FG” denotes a sidewall of the active region 110a covered by the gate pattern 140. Accordingly, “FG” may correspond to the sidewall of the active region exposed by the lower field trench 130f.

Forming the gate pattern 140 may include removing the lower hard mask 112 and the sacrificial spacer 125 so as to form a gate layer on the substrate exposing the sidewalls and bottom of the upper gate trench 120g, and then pattern the gate layer. The gate pattern 140 may include a gate dielectric layer 134 and a gate electrode 136 which are sequentially stacked. The gate dielectric layer 134 may be, for example, a silicon oxide layer or a high-k dielectric layer, The gate electrode 136 may include, for example, at least one in selected from a polysilicon layer, a metal layer and a silicide layer. Before patterning the gate layer, a capping layer 143 used as a hard mask may be formed. The capping layer 143 may be, for example, a silicon nitride layer.

An insulating spacer 145 filling a space between the sidewall of the upper gate trench 120g and the gate pattern 140 may be formed. Forming the insulating spacer 145 may include forming a spacer insulating layer on the substrate having the gate pattern 140, and anisotropically etching the spacer insulating layer.

Source and drain regions 150 may be formed in the active region 110a at both sides of the gate pattern 140. For example, the source and drain regions 150 may be formed in the active region adjacent to the sidewall and bottom of the insulating spacer 145.

Forming the source and drain regions 150 may include injecting impurity ions into the active region adjacent to the sidewall of the upper gate trench 120g to minimize the overlap area with the gate pattern 140, and diffusing the impurity ions into the active region adjacent to the bottom of the insulating spacer 145. Here, injecting impurity ions into the active region adjacent to the sidewall of the upper gate trench 120g may include injecting impurity ions into the active region 110a using the isolation layer 110s the gate pattern 140 and the insulating spacer 145 as ion injection masks. Accordingly, the overlap area between the source and drain regions 150 and the gate pattern 140 may be minimized, As a result, the overlap area between the source and drain regions 150 and the gate electrode 136 may be minimized.

A transistor having a recess channel structure and a fin structure may be provided as described above. In summary, the lower gate trench 130g is filled with the gate pattern 140, thereby forming the recess channel between the source and drain regions 150. Also the gate pattern 140 covers the sidewall of the active region adjacent to the bottom and sidewall of the lower gate trench 130g, and partially covers the bottom of the upper gate trench 120g adjacent to the lower gate trench 130g, thereby forming a fin structure.

Referring to FIGS. 1 and 8, first and second landing pads 155s and 155b electrically connected to the source and drain regions 150 may be formed by a self-align contact process. The first landing pad 155s may be electrically connected to one of the source and drain regions 150.

A lower insulating layer 160 may be formed on the substrate having the landing pads 155s and 155b. A direct contact plug 165 passing through the lower insulating layer 160 and electrically connected to the second landing pad 155b may be formed. A conductive line 170 covering the direct contact plug 165 may be formed on the lower insulating layer 160. The conductive line 170 may be defined as a bit line. In this case the gate electrode 136 may be defined as a word line. An upper insulating layer 175 may be formed on the substrate having the conductive line 170. The upper insulating layer 175 and the lower insulating layer 160 may be silicon oxide layers. A buried contact plug 180 passing through the upper insulating layer 175 and the lower insulating layer 160 and electrically connected to the first landing pad 155s may be formed. A data storage element 190 covering the buried contact plug 185 may be formed on the upper insulating layer 175. The data storage element 190 may be a storage capacitor. Thus, a memory device such as, for example, a DRAM employing a transistor having the recess channel and fin structures as a cell transistor can be provided.

According to exemplary embodiments of the present invention as described above, a transistor that minimizes an overlap area between source and drain regions and a gate electrode and has a recess channel structure and a fin structure is provided, As the overlap area between the source and drain regions and the gate electrode is minimized, gate induced drain leakage (GIDL) of the transistor can be suppressed. Also, because of the recess channel and fin structures, the short channel effect can be inhibited and the on-current characteristics of the transistor can be improved as well, Therefore, the data retention characteristics of a memory device such as, for example, a DRAM employing the transistor as a cell transistor can be improved.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A semiconductor device, comprising:
an upper gate trench crossing an active region of a semiconductor substrate;
a lower gate trench overlapping the upper gate trench at both ends, disposed at a lower level than the upper gate trench, and having a smaller width than the upper gate trench and wherein the lower gate trench is spaced apart from sidewalls of the upper gate trench, and
a gate pattern partially covering the bottom of the upper gate trench between the sidewall of the upper gate trench and the lower gate trench filling the lower gate trench, and covering sidewalls of the active region adjacent to the bottom and sidewalls of the lower gate trench.

2. The semiconductor device according to claim 1, wherein the gate pattern is spaced apart from the sidewall of the upper gate trench.

3. The semiconductor device according to claim 1, further comprising an insulating spacer interposed between the sidewall of the upper gate trench and the gate pattern.

4. The semiconductor device according to claim 3, further comprising source and drain regions disposed in the active region adjacent to sidewalls and the bottom of the insulating spacer.

5. The semiconductor device according to claim 1, further comprising a data storage element electrically connected to one of the source and drain regions.

6. The semiconductor device according to claim 1, wherein the gate pattern comprises a gate dielectric layer and a gate electrode which are sequentially stacked.

7. The semiconductor device according to claim 1, wherein a longitudinal width of the active region adjacent to the bottom of the lower gate trench covered by the gate pattern is equal to or greater than a lateral width of the active region adjacent to the sidewall of the lower gate trench covered by the gate pattern.

8. A method of fabricating a semiconductor device, comprising:
forming an isolation layer defining an active region in a semiconductor substrate;
forming an upper gate trench crossing the active region of the semiconductor substrate;
partially etching the bottom of the upper gate trench, thereby forming a lower gate trench having a smaller width than the upper gate trench to overlap the upper gate trench at both ends and wherein the lower gate trench is spaced apart from sidewalls of the upper gate trench.
partially etching the isolation layer adjacent to the lower gate trench to expose sidewalls of the active region adjacent to the bottom and sidewalls of the lower gate trench; and
forming a gate pattern that fills the lower gate trench, covers the sidewall of the active region adjacent to the bottom and sidewalls of the exposed lower in gate trench, and partially covers the bottom of the upper gate trench, and wherein the gate pattern is spaced apart from the sidewalls of the upper gate trench.

9. The method according to claim 8, wherein the forming of the upper gate trench comprises:
forming a mask partially exposing the active region and the isolation layer on the substrate having the isolation layer; and
etching the active region using the mask as an etch mask.

10. The method according to claim 9, wherein the forming of the lower gate trench comprises:
partially etching the isolation layer using the mask as an etch mask;
forming a sacrificial spacer on the sidewalls of the upper gate trench and the mask; and
etching the bottom of the upper gate trench using the mask and the sacrificial spacer as etch masks.

11. The method according to claim 10 wherein the partial etching of the isolation layer adjacent to the lower gate trench comprises:
etching the isolation layer adjacent to the lower gate trench using an isotropic etching process having a high etch rate with respect to the isolation in layer; and
removing the sacrificial spacer and the mask.

12. The method according to claim 8, wherein the forming of the gate pattern comprises;
forming a gate layer on a substrate exposing sidewalls of the active region adjacent to the sidewalls and bottom of the lower gate trench; and patterning the gate layer.

13. The method according to claim 8, further comprising forming an insulating spacer filling a space between the sidewall of the upper gate trench and the gate pattern.

14. The method according to claim 13, further comprising forming source and drain regions in the active region adjacent to the sidewalls and bottom of the insulating spacer.

15. The method according to claim 14, wherein the forming of the source and drain regions comprises:
injecting impurity ions into the active region adjacent to the sidewall of the upper gate trench; and
diffusing the impurity ions into the active region adjacent to the bottom of the insulating spacer.

16. The method according to claim 14, further comprising forming a data storage element electrically connected to one of the source and drain regions.

17. A method of fabricating a semiconductor device, comprising:
forming an isolation layer defining a plurality of active regions, the plurality of active regions each having major and minor axes and wherein the plurality of active regions are two-dimensionally arranged along the major and minor axes in a semiconductor substrate;
forming an upper trench crossing the active regions of the semiconductor substrate and extending to the isolation layer;
partially etching the bottom of the upper trench disposed in the active regions, thereby forming a tower gate trench having a smaller width than the upper trench to overlap the upper trench at both ends and wherein the lower gate trench is spaced apart from sidewalls of the upper trench in the active region;
partially etching the isolation layer adjacent to the tower gate trench to expose sidewalls of the active regions adjacent to the bottom and sidewalls of the lower gate trench, thereby forming a lower field trench having a greater width and a lower bottom than the lower gate trench; and
forming a gate pattern that fills the lower gate trench and the lower field trench, and partially covers the bottom of the upper trench and wherein the gate pattern is spaced apart from the sidewalls of the upper trench disposed in the active regions.

18. The method according to claim 17, wherein the forming of the upper trench comprises:
forming a mask having an opening partially exposing the active regions and the isolation layer, the mask including a lower hard mask, an upper hard mask and a sacrificial mask which are sequentially stacked, and the upper hard mask being formed of a material having an etch selectivity with respect to the lower hard mask and the isolation layer;
etching the active regions and the isolation layer exposed by the opening using the mask as an etch mask; and
removing the sacrificial mask.

19. The method according to claim 18, wherein the opening has a pocket structure so that the isolation layer between the active regions arranged along the major axis is covered by the mask.

20. The method according to claim 18, wherein the forming of the lower gate trench comprises:
forming a sacrificial spacer covering the lower hard mask, the upper hard mask and the sidewall of the upper trench;
anisotropically etching the bottom of the upper trench disposed in the active regions using the sacrificial spacer and the upper hard mask as etch masks; and
removing the upper hard mask.

21. The method according to claim 20, wherein when the upper hard mask is formed of the same material as the active regions, the upper hard mask is etched and removed while etching the bottom of the upper trench disposed in the active regions.

22. The method according to claim 20, wherein the forming of the tower field trench comprises:
anisotropically etching the isolation layer using the sacrificial spacer and the lower hard mask as etch masks and forming a preliminary tower field trench;
isotropically etching the preliminary lower field trench using an isotropic etching process having a high etch rate with respect to the isolation layer using the sacrificial mask and the lower hard mask as etch masks; and
removing the sacrificial spacer and the lower hard mask.

23. The method according to claim 22, wherein the preliminary lower field trench is formed to have a bottom disposed at a lower level than the lower gate trench.

24. The method according to claim 18, further comprising forming an insulating spacer filling a space between the sidewall of the upper trench and the gate pattern.

25. The method according to claim 24, further comprising forming source and drain regions in the active region adjacent to the sidewalls and bottom of the insulating spacer.

26. The method according to claim 25, further comprising forming a data storage element electrically connected to one of the source and drain regions.
